(19) United States
(12) Patent Application Publication
(10) Pub. No.: US 2015/0093706 A1
(43) Pub. Date: Apr. 2, 2015

(54) METHOD FOR RECORDING AN IMAGE AND ASSOCIATED MEDIUM

(71) Applicant: COMMISSARIAT A L'ENERGIE ATOMIQUE ET AUX ENE ALT, Paris (FR)

(72) Inventor: Christophe MARTINEZ, Grenoble (FR)

(73) Assignee: COMMISSARIAT A L'ENERGIE ATOMIQUE ET AUX ENE ALT, Paris (FR)

(21) Appl. No.: 14/496,332

(22) Filed: Sep. 25, 2014

(30) Foreign Application Priority Data
Sep. 30, 2013 (FR) 13 59398

(51) Int. Cl. G03F 7/20

(52) U.S. Cl. CPC G03F 7/2022; G03F 7/2051
USPC 430/324

(57) ABSTRACT

The invention relates to a method for recording a source image, in which a reproduction of the source image is made in the form of a matrix of elementary patterns.

The method comprises the following steps:
deposition (401) of a first opaque layer (42) on a first substrate (41);
etching (402) of the first opaque layer (42) so as to form a matrix of first cells (440) each having one from amongst several first predetermined patterns;
deposition of at least one second opaque layer (45); and
etching of the second opaque layer (45), so as to form a matrix of second cells (470) each having one from amongst several second pre-determined patterns, the elementary patterns being defined by the superimposition of a second pattern and a first pattern.

The invention also relates to an image medium obtained by means of such a method.

### TECHNICAL FIELD

The present invention relates to the field of recording an image on a medium using photo-lithography, and more particularly to the field of methods for storage of an image.

Storage of an image will here designate the storage of a reproduction of this image for the purposes of reading it later, using transparency reading. In general it involves a reproduction of this image with smaller dimensions, often as a single copy.

Throughout the text, the term “image” means any graphic representation such as a photograph, text, a table, a drawing etc.

The invention also relates to the field of image media made using such methods.

### STATE OF THE PRIOR ART

Many methods for recording an image on a medium using photo-lithography are known in the prior art. Here the field of storage of an image will be more specifically described, although the invention that is described below can be extended to the wider field of recording of an image using photo-lithography.

It is usual for images to be stored in digital form on storage media such as computer hard disks and recordable digital optical disks (CDs ROMs, DVDs etc.). Such media, however, have a limited lifetime, typically of the order of tens of years. Moreover, coding formats may become obsolete and prevent the image from being recovered from stored digital data.

Various methods offering long-term storage solutions with small overall dimensions are known in the prior art. These methods involve carrying out a screening (or rasterizing) of the image, then using maskless photo-lithography to etch a layer of opaque material deposited on a transparent substrate to reproduce the screened image in smaller dimensions. A storage medium is thus obtained wherein an image is stored in analogue format. An example of such an image storage method will be found in document EP 2 105 921.

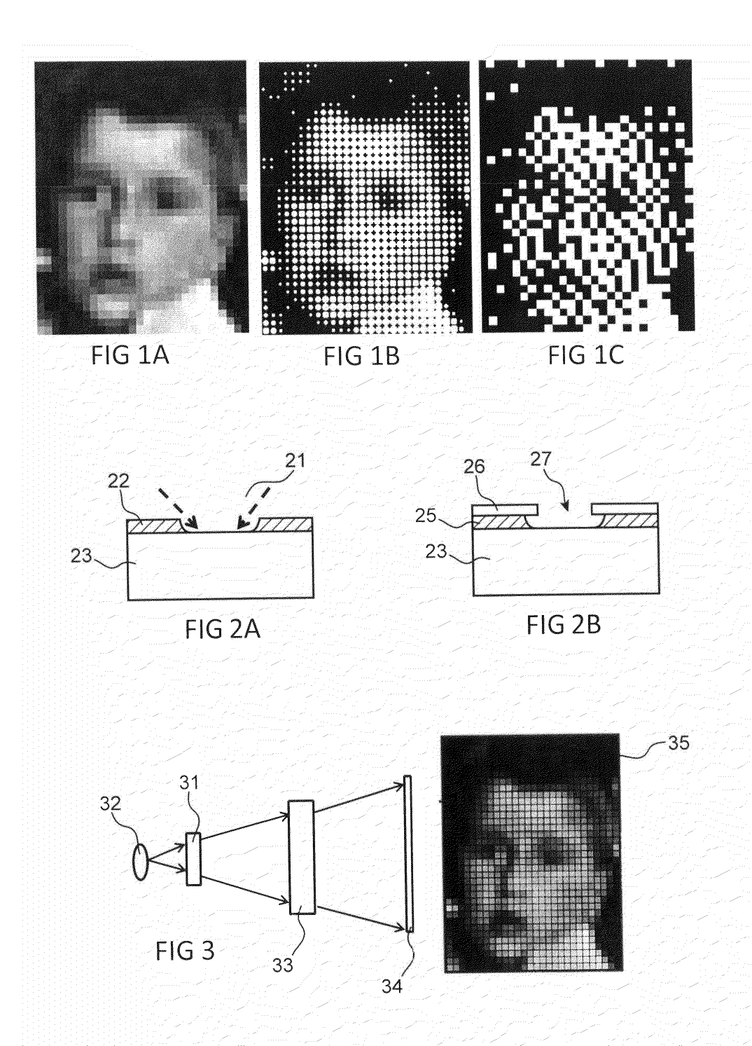

The screening step involves converting an image in grey levels, into a black and white image, made of a matrix of cells of the same dimensions called “screening cells”. The term “grey level” can also mean the gradations of intensity of a colour. For example frequency modulation screening is known wherein each cell is homogeneous: entirely black or entirely white. Amplitude modulation screening is also known wherein each cell contains a shape of variable size recorded in white on black or in black on white. FIG. 1A shows an image to be stored. FIG. 1B shows this image after amplitude modulation screening. FIG. 1C shows this image after frequency modulation screening.

Maskless photo-lithographic etching is carried out by direct writing using a laser, with no step involving masking of predefined zones. Maskless photo-lithographic etching can involve direct etching: the opaque material is photosensitive and the laser beam is applied directly on the layer of opaque material. FIG. 2A shows direct etching using maskless photo-lithographic etching. The laser beam 21 etches a layer 22 of photosensitive opaque material located on a transparent substrate 23. Maskless photo-lithographic etching may be indirect etching. Indirect maskless photo-lithographic etching is shown in FIG. 2B. An opaque layer 25 covers a transparent substrate 23. The following steps are then carried out:
the opaque layer 25 is covered with a sacrificial photosensitive layer 26 such as a photosensitive resin:
the laser beam is applied to the photosensitive sacrificial layer 26 so as to transform the material in the exposed zones;
the transformed zones of the layer 26 are etched so as to make the layer 25 accessible in front of the uncovered zones 27;
the opaque material 25 is etched by applying a chemical compound to which the remaining photosensitive sacrificial layer 26 is not sensitive and to which the opaque layer is sensitive: in this way the chemical compound etches the opaque layer 25 through the opening 27;
the sacrificial photosensitive layer 26 is removed.

The storage medium can be read using a low-pass filter which eliminates fine variations in the screening structure below the scale of the cell, so as to retain only changes averaged at the scale of a few cells. The storage medium may be read, for example, using simple means of optical enlargement. The storage medium 31 is lit by a light source 32. An optical system 33 images the storage medium 31 on a detector 34, such as a matrix detector. The optical system 33 has an optical transfer function which introduces optical blurring similar to a Gaussian spot with a width (or “waist”) equal to a few pixels, typically two or three. The magnification of the optical system 33 is such that the size of a screening cell corresponds to the size of a pixel of the matrix detector 34. The dark hues coded in the storage medium 31 relate to the opaque layer and the light hues relate to the openings which are etched in the opaque layer and which expose the surface of the transparent substrate. The image 35 is obtained on the matrix detector 34.

If the image is in colour, several reproductions are stored which correspond to the decomposition of the image into three components, for example:
red, green, blue (RGB decomposition); or
hue, saturation, light intensity (HSV decomposition); or
light intensity, first chromatic component for colours between green and red, second chromatic component for colours between blue and yellow (LAB decomposition, or breakdown).

For the opaque layer the existing methods typically use a layer of platinum oxide PtOₓ with a thickness of about 60 nm, where x is in particular a real number between 1 and 2. Such a platinum oxide layer has a transmission of less than 5% for a minimum opening size which is equivalent to a disk of diameter 1.5 μm.

These methods exhibit limitations in cases where it is desired to store high-definition images. These high-definition images are made, for example, using new generations of digital photo equipment.

For example, a high-definition image is coded as 8 bits: each pixel of the image can take a grey level from amongst 256 (2⁸) available grey levels. In order to code this many grey levels in the storage medium, the known solution is that one pixel of the image is equivalent to large number of screening cells. A drawback of such a solution is that the surface area of the zone of the storage medium corresponding to this-high definition image increases.

One objective of the present invention is to propose a method for recording a source image which does not exhibit at least one of the drawbacks of the prior art.

In particular, one objective of the present invention is to propose a method for recording a source image using photo-lithography, which allows compact writing of source images to be achieved.

In particular, one objective of the present invention is to propose a method for recording a source image using photo-lithography, which allows compact writing of high-definition source images, typically with a definition of at least 8 bits, for example of 16 bits, to be achieved.

Another objective of the present invention is to propose an image medium obtained using such a process.

### DESCRIPTION OF THE INVENTION

The present invention is defined by a method for recording a source image wherein a reproduction of the source image is made in the form of a matrix of elementary patterns, the method comprising the following steps:
deposition of a first opaque layer on a first substrate;
etching of the first opaque layer over its entire thickness by photo-lithography, so as to form a matrix of first cells each having one from amongst several first predetermined patterns.

The method according to the invention moreover includes the following steps:
deposition of at least one second opaque layer so that the second opaque layer is superimposed onto the first opaque layer; and
etching of said second opaque layer over its entire thickness by photo-lithography, so as to form on the second opaque layer a matrix of second cells each of which has one from amongst several second predetermined patterns, said elementary patterns each being defined by the superimposition of a first pattern taken from amongst several said first predetermined patterns and of a second pattern taken from amongst said second predetermined patterns and where at least one elementary pattern is defined by the superimposition of a first pattern on a second pattern of a different shape.

Throughout the text, a layer of opaque material, or opaque layer, means a layer whose transmission coefficient is less than that of the first substrate. This transmission coefficient may be zero, seeing that it allows the elementary pattern obtained by the superimposed layers to be formed. The transmission coefficient is defined for visible wavelengths, preferably between 400 nm and 800 nm.

Preferably, the recording method according to the invention stores a source image in a storage medium comprising a first transparent substrate and a second transparent substrate. According to such a method:
the first opaque layer is formed on the first transparent substrate;
the etching steps are carried out using maskless photo-lithography; and
the deposition of a second opaque layer is carried out so that the second opaque layer is between the first opaque layer and the second transparent substrate.

The first and the second opaque layers preferably have respective degrees of opacity which differ from one another. The term degree of opacity means the extinction level or extinction coefficient, that is, the inverse of the transmission level or coefficient. The degree of opacity is preferably defined for visible wavelengths, preferably between 400 nm and 800 nm.

The first and the second opaque layers preferably have different thicknesses and are formed of the same material. Thus first and second opaque layers are made which have respective degrees of opacity which differ from one another.

Alternatively, the first and second opaque layers may each consist of a different material. These materials advantageously exhibit different light transmission properties. Thus first and second opaque layers can be made which have the same thickness and with respective degrees of opacity which differ from one another.

The method according to the invention may comprise an initial step for coding of the source image, using frequency modulation screening or amplitude modulation screening, where the screening uses elementary patterns according to the invention.

According to one advantageous embodiment:
each first cell and each second cell is either fully etched or non-etched, thus defining, by superimposition, a first series of elementary patterns available to carry out reproduction of the source image; and
frequency modulation screening of the source image is performed using coding patterns chosen from amongst said first series of elementary patterns.

According to one alternative of this embodiment:
each first cell and each second cell is etched, or non-etched, or etched so as to form a closed transparent area in a cell with opaque edges or a closed opaque area in a cell with transparent edges, thus defining, by superimposition, a second series of elementary patterns available for carrying out the reproduction of the source image; and
amplitude modulation screening of the source image is performed using coding patterns chosen from amongst said second series of elementary patterns.

The method according to the invention, when it carries out storage as described above, can comprise the following steps:
deposition of the second opaque layer on the second transparent substrate;
etching, by photo-lithography, of the second opaque layer;
bonding of the second opaque layer deposited on the second transparent substrate, onto the first opaque layer.

Alternatively, the method according to the invention, when it carries out storage as described above, can comprise the following steps:
at least one cycle comprising the following steps:
   deposition of a transparent material onto the first previously etched opaque layer;
   deposition of the second opaque layer on the transparent material;
   etching, by photo-lithography, of the new opaque layer;
bonding of the second transparent substrate onto the second previously etched opaque layer.

Alternatively, the method according to the invention, when it carries out storage as described above, can comprise the following steps:
at least one cycle comprising the following steps:
   bonding of an intermediate transparent substrate onto the first previously etched opaque layer;
   etching by photo-lithography of the second opaque layer deposited on the intermediate transparent substrate;
bonding of the second substrate onto the second previously etched opaque layer.

Alternatively, the method according to the invention, when it carries out storage as described above, can comprise the following steps:
at least one cycle comprising the following steps:
   deposition of the second opaque layer onto the previously etched opaque layer;
   etching, by photo-lithography, of the second opaque layer;
bonding of the second transparent substrate onto the second previously etched opaque layer.

Thus in each of these alternatives the deposition of the second opaque layer is carried out after etching of the first opaque layer.

The etching of the second opaque layer may be carried out before or after deposition of the second opaque layer on the first etched opaque layer.

The method according to the invention, when it carries out storage as described above, can comprise the following steps:
decomposition of an image to be stored into three components;
recording of said three components, each in a storage zone of the storage medium and between the first transparent substrate and the second transparent substrate, at least one of said components being recorded in a storage zone, called the high-definition storage zone, using a method which performs storage as described above, and at least one of said components being recorded in a storage zone, called the low-definition storage zone, by etching a single opaque layer using photo-lithography.

Preferably, an image to be stored is broken down, or decomposed, using a HSV decomposition to obtain a “hue” component, a “saturation” and a “light intensity” component, the “hue” and “saturation” components are recorded in the high-definition storage zone, and the “light intensity” component is recorded in the low-definition storage zone.

The method according to the invention advantageously comprises a step of transparency reading (or in other words transmission reading) of the reproduction of a source image, comprising the following steps:
illumination of said reproduction using a light source located on one side of said reproduction;
detection of an image of said reproduction, using a detector located on the side of said reproduction away from that of the light source.

The invention also relates to an image medium wherein a reproduction of a source image is stored in the form of a juxtaposition of elementary patterns, said image medium comprising, on a first substrate, a first opaque layer etched over its entire thickness using photo-lithography and forming a matrix of first cells each having one from amongst several predetermined first patterns. The medium according to the invention has the following characteristics:
the image medium comprises at least one second opaque layer, etched over its entire thickness using photo-lithography, forming a matrix of second cells, each second cell having one from amongst several second predetermined patterns; and
the second opaque layer is located on the first opaque layer so as to define said elementary patterns, formed by the superimposition of a first pattern and a second pattern, and at least one elementary pattern being defined by the superimposition of a first pattern on a second pattern of a different shape.

The image medium according to the invention can form a source image storage medium and:
comprise at least one storage zone, called the high-definition zone, wherein the reproduction of the source image is stored;
comprise a first transparent substrate and a second transparent substrate, the first opaque layer being located on the first transparent substrate and the second opaque layer being located between the first opaque layer and the second transparent substrate.

The first opaque layer and the second opaque layer may have different thicknesses, with each thickness being between 10 nm and 200 nm.

Each first cell and each second cell can be fully etched or not etched.

Alternatively, each first cell and second cell may be fully etched or not etched, or etched so as to form a closed transparent area in a cell with opaque edges or a closed opaque area in a cell with transparent edges, closed areas formed in various first cells having different dimensions, closed areas formed in different second cells having different dimensions.

In one preferred embodiment, the image medium is a storage medium and it comprises:
a first high-definition storage zone, wherein a reproduction of a first source image is stored which is equivalent to a first from amongst three components of an image to be stored;
a first low-definition storage zone, wherein a reproduction of a second source image is stored which is equivalent to the second component of the image to be stored, the low-definition storage zone comprising, between the first transparent substrate and the second transparent substrate, a single opaque layer etched using photo-lithography; and
a second high-definition storage zone or a second low-definition storage zone wherein a reproduction of a third source image is stored which is equivalent to the third component of the image to be stored.

The invention also relates to a system comprising an image medium according to the invention and means for transparency reading (or in other words transmission reading) of the reproduction of a source image located in this image medium.

The means for transparency reading comprise a light source located on one side of said image medium, and a detector located on the side of the image medium away from that of the light source.

### BRIEF DESCRIPTION OF THE ILLUSTRATIONS

The present invention will be better understood on reading the description of example embodiments given purely as an indication and in no sense restrictively, making reference to the appended illustrations in which:

FIG. 1A shows an image to be stored;

FIG. 1B shows the image in FIG. 1A after amplitude modulation screening;

FIG. 1C shows the image in FIG. 1A after frequency modulation screening;

FIG. 2A shows direct etching using maskless photo-lithography;

FIG. 2B shows indirect etching using maskless photo-lithography;

FIG. 3 shows an installation for reading a storage medium;

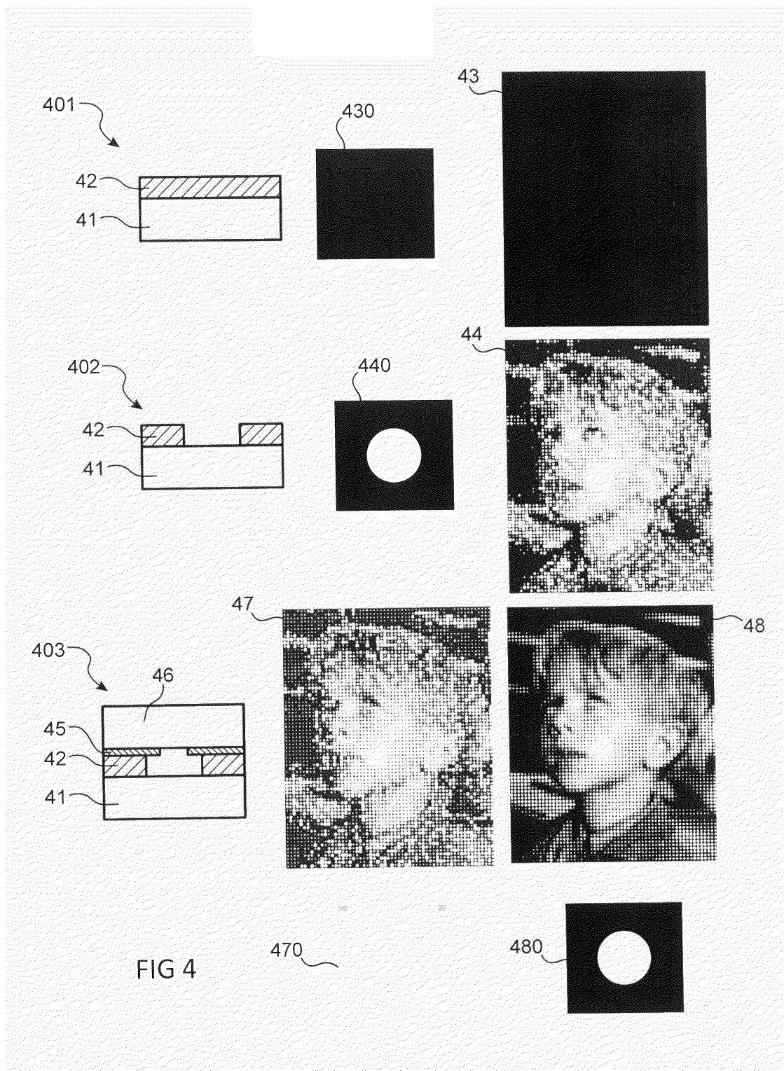

FIG. 4 shows an embodiment of the recording method according to the invention;

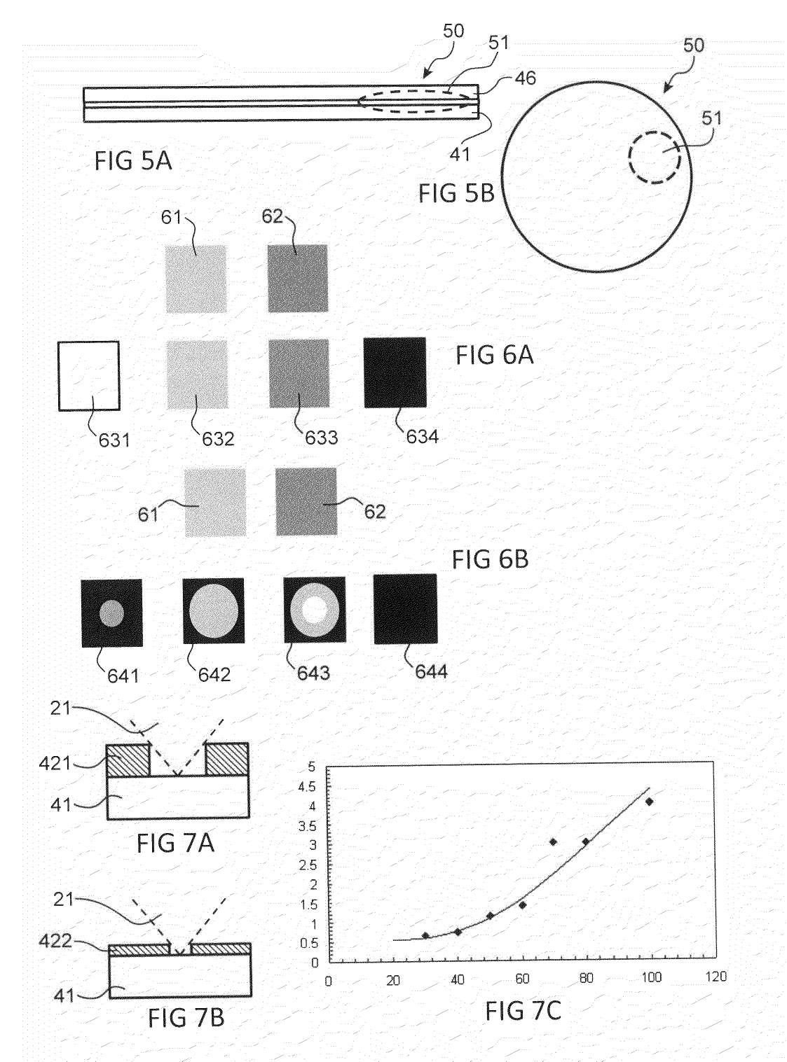

FIG. 5A shows a profile view of a schematic representation of an image medium according to the invention;

FIG. 5B shows front view of a schematic representation of an image medium according to the invention;

FIG. 6A shows a first example of combinations of first and second cells, forming elementary patterns according to the invention;

FIG. 6B shows a second example of combinations of first and second cells, forming elementary patterns according to the invention;

FIG. 7A shows a maskless photo-lithography step for a thick opaque layer;

FIG. 7B shows a maskless photo-lithography step for a thin opaque layer;

FIG. 7C shows a minimum opening size in a cell as a function of an opaque layer thickness corresponding to that cell;

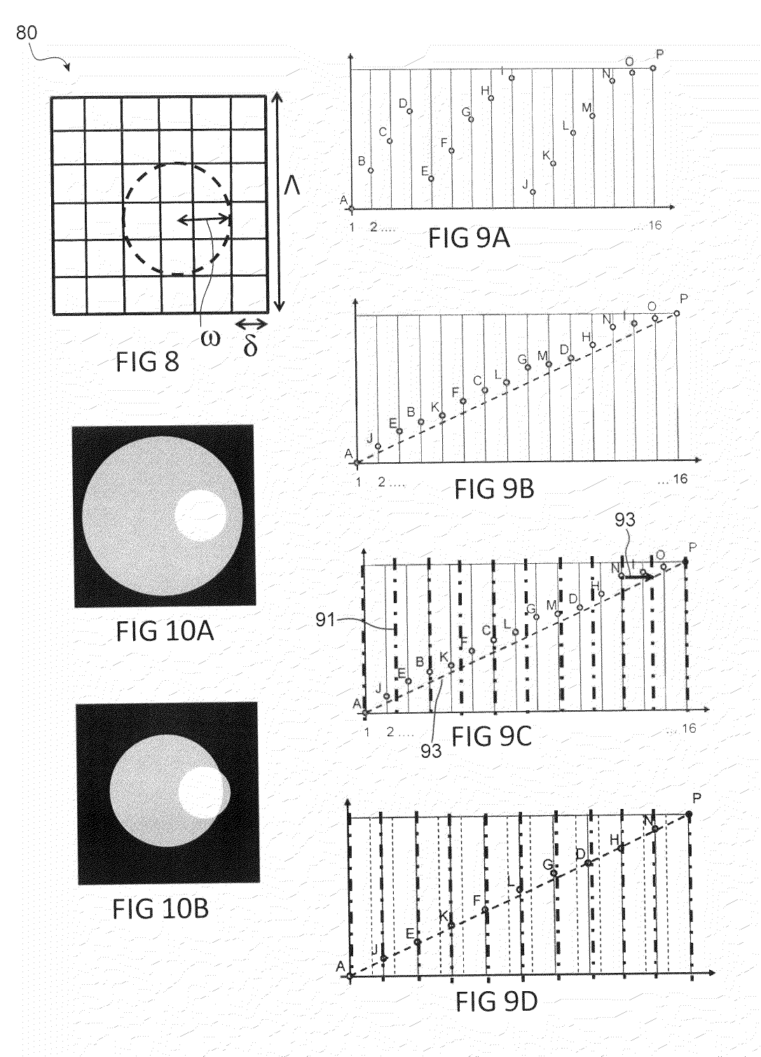

FIG. 8 shows an opening in a cell and the decomposition of a cell according to a grid which corresponds to the displacement movements of a laser beam relative to the cell;

FIGS. 9A to 9D show various steps in the creation of a library of elementary patterns suitable for a desired screening dynamic range;

FIGS. 10A and 10B show a fault in the alignment of a first pattern relative to a second pattern;

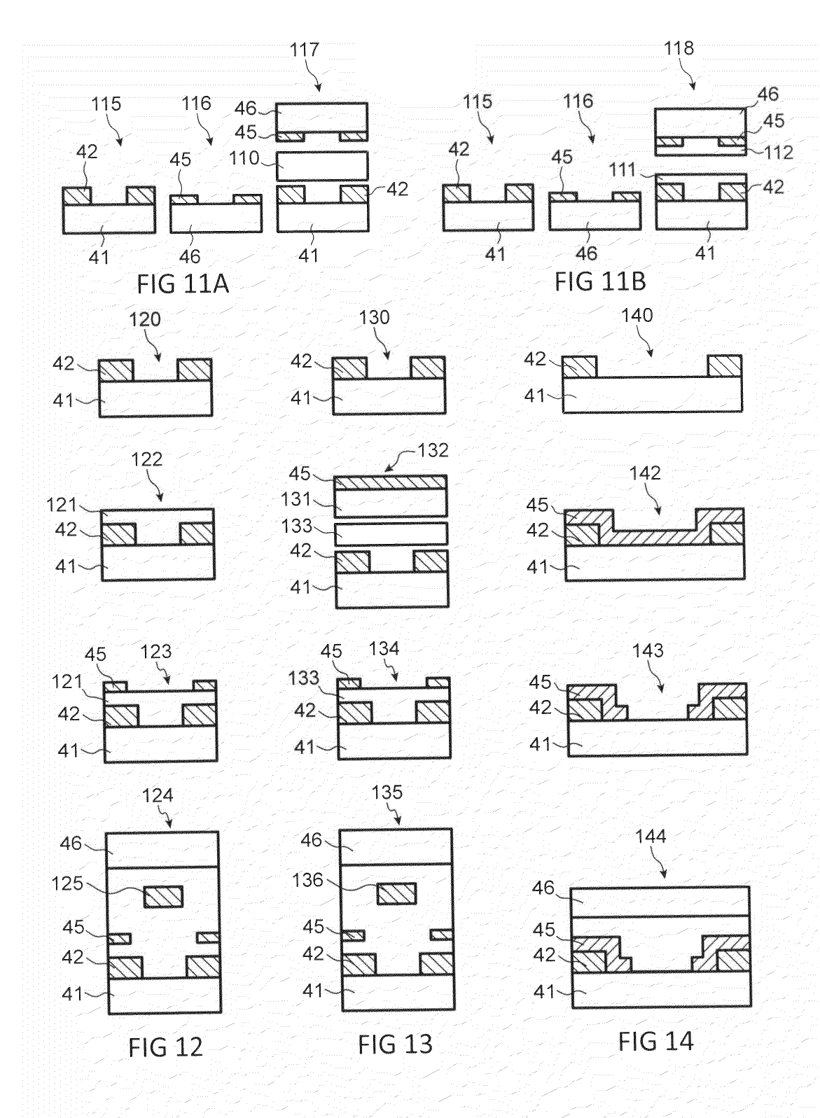

FIGS. 11A and 11B show two alternatives of a first embodiment of the recording method according to the invention;

FIG. 12 shows a second embodiment of the recording method according to the invention;

FIG. 13 shows a third embodiment of the recording method according to the invention;

FIG. 14 shows a fourth embodiment of the recording method according to the invention;

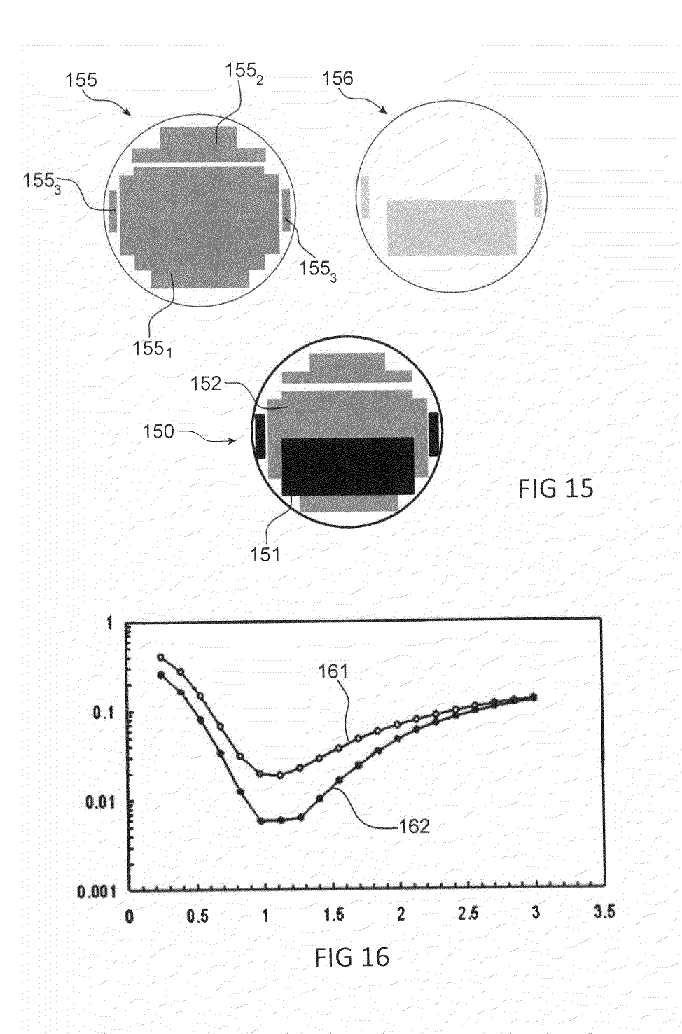

FIG. 15 shows an image medium according to the invention comprising a high-definition storage area and a low-definition storage area; and

FIG. 16 shows a comparison of the mean square error between a source image and its representation in the form of elementary patterns, in the case of storage according to the prior art and in the case of storage according to the invention.

### DETAILED DESCRIPTION OF PARTICULAR EMBODIMENTS

FIGS. 1A, 1B, 1C, 2A, 2B and 3 have already been described in the introduction.

First of all, with reference to FIG. 4, a method for recording a source image according to the invention will be described.

The specific case wherein the recording method according to the invention forms a storage method has been chosen for description. The image medium made may then be called the “storage medium”.

The recording method according to the invention comprises a first step 401, for the deposition of a first opaque layer 42 on a first transparent substrate 41. At this stage, the first opaque layer 42 forms a matrix 43 of first cells 430 which are all identical and opaque.

During a second step 402, etching of the first opaque layer 42 is carried out using photo-lithography.

The etching using photo-lithography may involve maskless etching, in particular in the context of storage of a single copy of a source image.

Alternatively, etching using photo-lithography may involve etching using a mask. Etching using a mask uses etching of a set of patterns in a source mask. As many copies of the set of patterns as desired are reproduced on substrates by projections through this mask. This alternative is advantageous for the reproduction of several copies of an image. This, for example, will be the case for product marking applications for the purpose of accurate identification of the product's manufacturer.

A matrix 44 of first cells 440 is thus formed, each cell having one from amongst several predetermined patterns. The first opaque layer is etched over its entire thickness.

In a third step 403, at least one second opaque layer 45 is deposited, so that this second opaque layer 45 is placed between the first opaque layer 42 and a second transparent substrate 46, and this second opaque layer is etched. One can also speak about the creation of at least one second opaque layer, so that this second opaque layer 45 is between the first opaque layer 42 and the second transparent substrate 46. The second transparent substrate 46 acts as a protective layer for the etched opaque layers. The method according to the invention is not limited to a given order for the steps for deposition of the second opaque layer 45 and etching of the latter, as the following examples show. The second opaque layer 45 is also etched using photo-lithography (with a mask, or by a maskless method). The second opaque layer is etched over its entire thickness. This etching forms a matrix 47 of second cells 470, each cell having one from amongst several pre-determined patterns. The superimposition of the matrix 44 of first cells onto the matrix 47 of second cells forms a matrix 48 of cells 480 each having an elementary pattern formed by the superimposition of a second pattern on a first pattern. At least one elementary pattern is formed by the superimposition of a second pattern on a first pattern, said second pattern being different from the first.

The matrix 48 is a matrix of elementary patterns and is equivalent to a reproduction, in smaller dimensions, of a source image, where this source image has undergone screening.

Thus it can be seen that for a given cell size, the invention allows a greater number of elementary patterns to be obtained which are available to build a reproduction, with smaller dimensions, of the source image. Thus all grey levels of a high-definition image could be coded using a limited number of cells. Thus compact storage of a high-definition source image, typically with a definition of at least 8 bits, can be achieved.

It should be noted that this effect is achieved without it being necessary to have recourse to etching methods or tools which have greater precision than in the prior art. It should also be noted that this effect is achieved without it being necessary to have recourse to etching methods or tools which allow areas of smaller dimensions to be etched than in the prior art.

In FIG. 4, the example of two opaque layers has been taken, but more than two opaque layers may be envisaged, for example 3, 4, 5 or 6.

The example of etching of a cell by the creation of a circular opening (or disk) in the cell has been taken. This example is not restrictive, and other examples will be listed with reference to FIGS. 6A and 6B.

The etching processes use photo-lithographic methods which offer etching resolutions in an opaque layer of the order of μm.

Multi-level screening or multi-layer screening can also be used to describe the method according to the invention.

Alternatively, the first substrate is not necessarily transparent and the second opaque layer 46 is not covered with a second transparent substrate. This alternative is equivalent to a recording of an image on a medium using photo-lithography. Here also the method according to the invention offers excellent image definition, for a smaller recording area. This variant is advantageously combined with the use of etching using photo-lithography with masking.

FIG. 5A shows a profile view of a schematically represented image medium 50 obtained using a recording method according to the invention. More specifically it relates to a storage medium 50, obtained using a storage method as described with reference to FIG. 4. The matrix of elementary patterns defined previously is formed in a high-definition storage zone 51 between the first transparent substrate 41 and the second transparent substrate 46. FIG. 5B shows a front view of the storage medium 50, schematically represented.

The first transparent substrate and the second transparent substrate each consist, for example, of a layer of quartz or of sapphire. The first transparent substrate and the second transparent substrate can also be made of a flexible plastic material or a rigid plastic material such as those used to make optical disks. The thickness of the first and second transparent substrate is of the order of nm, for example less than 1 mm and in particular equal to 0.7 mm.

Each opaque layer consists, for example, of a metallic layer such as a layer of chromium, a layer of titanium nitride or a layer of platinum oxide PtOₓ. The thickness of an opaque layer is generally less than 200 nm, or even less than 100 nm, for example equal to 60 nm, 40 nm or 30 nm.

FIG. 6A shows a first example of combinations of first and second cells, forming elementary patterns according to the invention

It can be seen that the first non-etched cell 61 has a transmission coefficient which is greater than that of the second non-etched cell 62. The transmission coefficient depends on the thickness of the corresponding opaque layer. For example a layer of thickness 40 nm of platinum oxide has a transmission coefficient of close to 5% whereas a 30 nm thick layer of platinum oxide has a transmission coefficient of close to 10%.

Each first cell 61 is either fully etched or not etched. Each second cell 62 is either fully etched or not etched. A set of four elementary patterns 631, 632, 633 and 634 is thus obtained which correspond, respectively, to the superimposition:
of a fully etched second cell 62 on a fully etched first cell 61;
of a fully etched second cell 62 on a non-etched first cell 61;
of a non-etched second cell 62 on a fully etched first cell 61; and
of a non-etched second cell 62 on a non-etched first cell 61.

These four elementary patterns 631, 632, 633, 634 define four coding patterns available in the context of frequency modulated screening. The grey level in such a coding pattern corresponds to the transmission coefficient of the associated elementary pattern.

An example of frequency modulation screening is Floyd Steinberg type error distribution dithering. This involves comparing, for each pixel in an image, its grey level with the grey level of two coding patterns (black or white). The image is coded by associating one of the coding patterns with each pixel. In order to do this the following are taken into consideration:
the coding pattern whose grey level is the closest to that of the pixel to be coded; and
the sum of the errors associated with the previous codings, where each error corresponds to the difference (positive or negative) between a grey level of a pixel and the grey level of the associated coding pattern.

This principle is readily adapted to a number N of coding patterns, where N is greater than 2. Known software such as “Gimp” allows Floyd Steinberg type error distribution dithering over N coding patterns to be carried out, where N is greater than 2.

It will be seen that a pixel of the source image can be divided into several zones to be associated with one coding pattern.

Each opaque layer is etched so as to create a predetermined checkerboard.

FIG. 6B shows a second example of combinations of first and second cells, forming the elementary patterns according to the invention. FIG. 6B corresponds to the case of amplitude modulation screening.

Each first cell 61 is either fully etched or non-etched, or etched so as to draw a transparent closed area in a cell with opaque edges or a closed opaque area in a cell with transparent edges.

In FIG. 6B are examples of:
a first cell 61 either non-etched, or wherein a circular opening having a first diameter has been etched, centred on the cell; and
a second cell 62 either non-etched, or wherein a circular opening having a second diameter has been etched, centred on the cell.

A set of four elementary patterns 641, 642, 643 and 644 are thus obtained which are equivalent, respectively to the superimposition:
of a second non-etched cell 62 on a first cell 61 wherein a circular opening with a first diameter has been etched;
of a second cell 62 wherein a circular opening with a second diameter has been etched, on a first non-etched cell 61;
of a second cell 62 wherein a circular opening with a second diameter has been etched, on a first cell 61 wherein a circular opening with a first diameter has been etched; and
of a non-etched second cell 62 on a non-etched first cell 61.

In practice non-circular openings could be envisaged, for example ovals. An opening is considered to have a circular or oval shape without taking edge defects associated with photo-lithographic etching into consideration. Opaque shapes on a transparent background could also be envisaged. Each cell could moreover be etched using openings of different dimensions, for example disks of different diameters. The solutions could be varied between one layer and another. In order to etch an opening in a cell with opaque edges, laser impacts could be carried out by displacement movements of the laser beam starting from the centre of the cell. In order to etch a cell so as to obtain an opaque closed area in a cell with transparent edges, laser impacts could be carried out by displacement movements of the laser beam on the edges of the cell.

The four elementary patterns 641, 642, 643, 644 define four coding patterns available in the context of amplitude modulated screening. The grey level in such a coding pattern is equivalent to the mean transmission coefficient for the associated elementary pattern.

In the context of amplitude modulation screening, each pixel is coded using the coding pattern whose grey level is closest to the grey level of said pixel.

It will be seen that a source image pixel can be divided into several zones to be associated with one coding pattern.

The advantage of amplitude modulation screening over frequency modulation screening is that there is a direct link between a source image pixel and the associated elementary pattern.

According to one advantageous embodiment:
the cells of an opaque layer are etched so as to form, in a cell, a transparent closed area in a cell with opaque edges; and
the cells of an opaque layer located above are etched so as to form, in a cell, an opaque closed area in a cell with transparent edges.

This embodiment will be called “embodiment with cross-polarisations of opaque layers”. An example of such an embodiment is shown in FIGS. 12 and 13.

FIG. 7A shows a maskless photo-lithography step for a thick opaque layer 421. It can be seen that the thickness of the opaque layer associated with the conical shape of the focussed laser beam 21 implies that there is a minimum size for the opening that can be etched in the thick opaque layer 421. For example, for a thickness of 100 nm for an opaque layer made of platinum oxide, the minimum opening is a disk of diameter 4 μm. In the case of indirect maskless photo-lithography or photo-lithography with a mask, the same effect is observed: if the attack by the chemical compound occurs deep within the opaque layer it spreads laterally.

FIG. 7B shows a maskless photo-lithography step for a thin opaque layer 422. As previously, the thickness of the opaque layer implies that there is a minimum size for the opening that can be etched in the thin opaque layer 422. This thinner the layer then the smaller the minimum size is. For example, for a thickness of 25 nm for an opaque layer made of platinum oxide, the minimum opening is a disk of diameter 0.6 μm.

FIG. 7C shows a graph representing the minimum diameter of a disk which can be etched in an opaque layer of platinum oxide using maskless photo-lithography, as a function of the thickness of the opaque layer. The abscissa axis is graduated in nm. The ordinate axis is graduated in μm. This figure clearly shows the fact that the thinner the opaque layer, then the smaller the minimum size of an opening that may be etched in the layer. It will be observed that this minimum size of opening also depends on the diffraction limit of the etching tool.

The same is observed in the case of etching using photo-lithography with a mask.

As stated with reference to FIG. 6B etching one opening in a cell from amongst several predetermined openings may be envisaged. The predetermined openings are the openings that may be etched by successive opening enlargement steps, starting from the minimum opening size. The successive steps are equivalent, for example, to the displacement of the laser beam on the cell, or to increases in the intensity of a fixed laser beam. Thus the thinner the opaque layer, the greater the number of predetermined openings a given size of cell will offer, since the openings start from a very small size. However, the thinner the opaque layer is, the greater the transmission coefficient of this layer will be. As seen earlier, during reading of the storage medium, the dark hues coded in the storage medium relate to the opaque layer and the light hues relate to the openings etched in the opaque layer. In order to optimise the detection dynamic range, the dark and light hues must be the most extreme possible. For the light hue the light source will be supplied so as to generate a signal which is as close as possible to the upper linear detection limit of the matrix detector. For the lower limit, the only adjustable variable relates to the transmission coefficient of the opaque layer. It can therefore be seen that the two criteria for the resolution of the etching in the opaque layer and for the reading dynamic range of the storage medium are contrary conditions in terms of the thickness of the opaque layer.

It can be seen that the same reasoning applies in the case of etching of a cell in order to achieve an opaque area in a cell with transparent edges. The cell is etched by etching all around the opaque area and the thickness of the opaque layer is then associated with a maximum size of the opaque area in a cell with transparent edges.

The invention, in that it proposes superimposing at least two opaque layers, provides a clever way of reconciling these two criteria. Using a first thin opaque layer, openings with small dimensions can be etched. As a result of the superimposition of at least two opaque layers, very low transmission coefficients can be achieved for the layer stack, for example of less than 5%. Preferably, different thicknesses are chosen for each of the opaque layers according to the invention.

The explanations above relate more specifically to the case of amplitude modulation screening, but these advantages are also found in a context of frequency modulation screening. According to FIG. 6A each opaque layer is then etched in a chequered pattern, where each box in the chequered pattern is either completely etched or non-etched. Thus it can be seen that a thin opaque layer means that chequered pattern boxes with small dimensions can be created. The superimposition of opaque layers, however, prevents this resulting in a loss of reading dynamic range.

For example, take two opaque layers. The first opaque layer exhibits a transmission Tₐ. The second opaque layer exhibits a transmission T_{b}. In each cell of the first opaque layer a disk of radius rₐ is etched, centred on the cell. In each cell of the second opaque layer a disk of radius r_{b} is etched, centred on the cell. Each cell is a square with a side of length Λ. For each cell, the superimposition of the second opaque layer on the first opaque layer will correspond to a grey level Γ_{ab} (mean transmission coefficient of a cell where the two layers a and b are stacked), then:

$${Γ}_{ab} = ( {T}_{a} \cdot {T}_{b} \times {Λ}^{2} + {T}_{a} \cdot ( 1 - {T}_{b} ) \times π \cdot {r}_{b}^{2} + ( 1 - {T}_{a} ) \times π \cdot {r}_{a}^{2} ) \frac{1}{{Λ}^{2}} \qquad ( 1 )$$

The grey level corresponds to cell areas weighted by the corresponding transmission coefficients, with the whole relative to the total surface area of the cell.

The following could be chosen, for example:
a first opaque layer of platinum oxide with a thickness of 40 nm, with transmission of about 5% and which gives a minimum pattern with a waist equal to around 800 nm; and
a second opaque layer of platinum oxide with a thickness of 30 nm, transmission of about 10% and which gives a minimum pattern with a waist equal to around 600 nm.

The reasoning is similar in the case of the recording of an image on a medium using photo-lithography.

The steps relating to the creation of a library of elementary patterns suitable for a desired screening dynamic range will now be described. In other words, let us take an image wherein each pixel can exhibit one from amongst 256 different grey levels, where the grey levels are regularly spaced from black to white, and it is wished to have available a library of 256 elementary patterns, such that this regular spacing of the corresponding grey levels is achieved, going from white up to black.

FIG. 8 illustrates a cell 80 of the first opaque layer according to the invention. The cell is a square with sides of length Λ. On this cell 80 an address matrix is defined which corresponds to a matrix of squares with sides of length δ. This matrix corresponds to the elementary displacement movements of a laser beam used for etching, relative to the cell 80. In this cell there is etched a disk of minimum radius ω.

Wider openings may be etched using one or more elementary displacement movements of the laser beam relative to the cell 80.

For a given cell, therefore, a set E of possible openings is obtained which correspond to a number Nmsk of possible first patterns:

$$Nmsk = \frac{{Λ}^{2} - π \cdot {ω}^{2}}{{δ}^{2}} \qquad ( 2 )$$

In the case of a cell with sides of length 2 μm and a method giving a minimum opening which corresponds to a disk of diameter 800 nm, an address matrix with step intervals equal to 100 nm would give access to a maximum of Nmsk=349 first patterns. These data are given as indications only. In practice the number of first patterns available is much smaller than the value given by equation (2), in particular since the etched opening dimensions cannot be accurately incremented in scale with the step intervals δ of the address matrix, and the edge effects on the etching correspondingly reduce the precision of manufacture.

According to the invention, use is made of:
a first opaque layer a, giving access to a number Nmskₐ of possible first patterns; and
a second opaque layer b, giving access to a number Nmsk_{b} of possible second patterns.

As a result of the superimposition of the two opaque layers a and b, the number of elementary patterns available is:

Nmsk_{ab}=Nmskₐ×Nmsk_{b} (3)

For example, Nmskₐ=349, for the dimensions Λ, δ and ω cited above. Nmsk_{b}=371, for the same dimensions Λ and δ, and for a value of ω which is slightly smaller (thickness of opaque layer b less than that of the opaque layer a). This then gives Nmsk_{ab}=129,479. Even when allowance is made for the actual precision of the etching, the calculations show that superimposing the two layers allows dynamic range levels reaching 16 bits to be achieved.

Detailed below is how, starting with a number P of elementary patterns that are actually available (allowing for the etching edge effects for example), a library of elementary patterns is organised, suitable for a given screening dynamic range. As seen earlier, the elementary patterns actually available depend on the dimension Λ of a cell, on the step intervals δ of the address matrix and on the radius ω of the minimum opening. They are also dependent on:
the polarity of the screening (depending on whether the opening in a cell of a layer makes a closed transparent area in a cell with opaque edges or a closed opaque area in a cell with transparent edges);
the writing method (the actual etching method used, which determines the difference between a desired opening and an opening actually obtained, where this difference is in effect due to edge effects);
the type of screening (shape of the opening: here in the form of a disk, but any closed area could be envisaged).

An opening in the form of a disk gives, for example:

$$Γ = \{ \begin{matrix}2 - p + {( - 1 )}^{p} \times \frac{π \cdot {ω}^{2}}{{Λ}^{2}} & si ω \leq \frac{Λ}{2} \\ 2 - p + {( - 1 )}^{p} \times ( \frac{π \cdot {ω}^{2}}{{Λ}^{2}} - 4 \cdot S ) & si ω > \frac{Λ}{2}\end{matrix} \qquad ( 4 )$$

where:
p is the polarity index (p=2 in the case of a transparent disk in a cell with opaque edges, p=1 in the case of an opaque disk in a cell with transparent edges),
S is a correction factor such that:

$$S = \frac{{ω}^{2}}{{Λ}^{2}} \times \{ a cos ( \frac{Λ}{2 \cdot ω} ) - \frac{Λ}{2 \cdot ω} \times sin [ a cos ( \frac{Λ}{2 \cdot ω} ) ] \} ,$$

and
Γ is the grey level or mean transmission coefficient of a cell in a layer, assuming a transmission coefficient of 0 for the opaque layer and of 1 for the opening.

FIG. 9A shows a diagram wherein 16 available elementary patterns, A to P, are shown, regularly spaced apart along an abscissa axis. The ordinate axis corresponds to the mean calculated or measured transmission coefficient which corresponds to each elementary pattern.

In FIG. 9A the elementary patterns are classified in the order in which they are obtained: each available first pattern is successively combined with all the available second patterns.

In FIG. 9B the elementary patterns are arranged in increasing order of mean transmission coefficient.

FIG. 9C shows the desired coding patterns for coding of an image. The vertical bars 91 in broken mixed lines each represent one of the desired X coding patterns. The straight dotted line 92 joins the two extreme desired ends for the coding. These extremities respectively correspond to a completely transparent elementary pattern and a completely opaque elementary pattern. The points A to P are moved in translation horizontally, so as to place them as close as possible to the points of intersection between the straight line 92 and each of the vertical bars 91. For example it can be seen that point N, moved in translation horizontally along arrow 93 moves exactly over one of these points of intersection. The horizontal axis corresponds to the abscissa axis of the orthogonal markers of FIGS. 9A to 9D. If the number of available elementary patterns in FIG. 9B is greater than X, some of the points A to P are removed (this is the case in the example shown in FIGS. 9A to 9D). If the number of available elementary patterns in FIG. 9B is less than X, some of the points A to P are duplicated. Thus the library of elementary patterns shown in FIG. 9D is obtained.

FIGS. 10A and 10B show a fault in the alignment of a first pattern relative to a second pattern. In the case of FIG. 10A the fault in the alignment does not alter the grey level of the elementary pattern of the cell. In the case of FIG. 10B the fault in the alignment alters the grey level of the elementary pattern of the cell. For each elementary pattern, the error in the grey level is predictable, since the following are known:
the first pattern and the second pattern which together form the elementary pattern, and
the ability to align one layer relative to the other, which is a function of the technique used to superimpose the two layers.

If the error in the grey level of an elementary pattern exceeds a pre-determined error threshold, this elementary pattern is removed from the library of elementary patterns shown in FIG. 9D. It is replaced by another elementary pattern, selected for instance from amongst the elementary patterns removed on passing from FIG. 9C to FIG. 9D.

It can be seen that, as shown in FIG. 10A, the etching corresponding to an amplitude modulation screening makes the method according to the invention robust in terms of alignment errors,

It can be seen that in the case of a frequency modulation screening, there is no point in creating a library of elementary patterns. For an image screened using frequency modulation over 2ⁿ grey levels, these grey levels are made using superimposition of n opaque layers.

We will now describe, with reference to FIGS. 11A to 14, various embodiments of the recording methods according to the invention. For legibility reasons, in these figures, a sectional view through a single cell is shown. This relates more specifically to storage methods.

In the first embodiment shown in FIG. 11A, the first transparent substrate 41 is covered by the first opaque layer 42. The first opaque layer 42 is etched using photo-lithography (step 115).

In parallel or sequentially, the second transparent substrate 46 is covered with the second opaque layer 45. The second opaque layer 45 is etched using photo-lithography (step 116).

Then the assembly formed from the second transparent substrate 46 and the second opaque layer 45 is deposited and bonded onto the first opaque layer 42 so that the second opaque layer 45 is placed between the first opaque layer 42 and the second transparent substrate 46.

In the alternative shown in FIG. 11A, the bonding is achieved using a layer of resin 110 deposited on the first or on the second opaque layer (step 117).

In another alternative of this first embodiment, shown in FIG. 11B, bonding is achieved by molecular adhesion. For this, a layer of transparent material 111, 112 is deposited on each of the first and second opaque layers 42, 45. Then these layers of transparent material 111, 112 are polished. The transparent material is, for example, aluminium oxide Al₂0₃ or silica SiO₂. The layers of transparent material are finally deposited on top of each other, and remain held together by molecular adhesion (step 118).

It should be noted that in this first embodiment, the second opaque layer 45 is turned over in order to bond it onto the first opaque layer. This must be taken into consideration when etching the second opaque layer 45.

Currently available bonding devices offer a precision of alignment for this last bonding step which is of the order of ±1 μm, which means that a square cell with sides of length Λ equals to at least 2 μm can be used (see FIG. 8).

FIG. 12 shows a second embodiment of the recording method according to the invention;

According to this second embodiment, the first transparent substrate 41 is covered by the first opaque layer 42. The first opaque layer 42 is etched using photo-lithography (step 120).

Then a layer of transparent material 121 is deposited on the previously etched opaque layer (step 122). This transparent material is, for example, silica SiO₂. Thus a flat surface is obtained on the side of the transparent material away from the first layer of opaque material 42.

A new opaque layer 45 is deposited on the transparent material 121. The new opaque layer 45 is etched using photo-lithography (step 123).

The method then comprises a final step 124 of bonding the second transparent substrate 46 onto the previously etched opaque layer 125. As for the first embodiment, this last bonding step can be carried out using resin or by molecular adhesion.

Steps 122 and 123 form a cycle which may be repeated as many times as desired. In other words, this second embodiment of the method according to the invention has at least one cycle comprising the following steps (with the previously etched opaque layer being initially the first opaque layer):
deposition of a transparent material onto the previously etched opaque layer;
deposition of a new opaque layer on the transparent material;
etching, using photo-lithography, of the new opaque layer which then forms the previously etched opaque layer.

This embodiment exhibits the advantage of allowing more than two opaque layers to be superimposed.

Moreover, the alignment of the opaque layers relative to each other is facilitated by the fact that the etching of an opaque layer is carried out after it is deposited on the lower opaque layer or layers. In effect, the alignment precision of the etching is better than that of the bonding. Precisions of 200 nm are commonly achieved using commercially available laser writing equipment.

Alignment also depends on the coefficient of thermal expansion a of the transparent substrates, such that:

ΔL=L·α·ΔT, where L is the width of the substrate, ΔT the variation in temperature during the operation of the method according to the invention and ΔL the variation in the substrate width resulting from the temperature variation ΔT.

For example, for a storage medium of diameter 200 mm, the expansion of the substrates remains less than 1 μm on condition that the temperature is stabilised at close to 0.7° C. for sapphire, at close to 0.5° C. for glass and at close to 10° C. for quartz. The clean rooms which use the lithography and bonding equipment have a stabilised and controlled temperature. The substrate support plates guarantee thermal uniformity to +/−0.5° C. It can be seen, therefore, that these allowable temperature variations are in accordance with what is technically feasible.

FIG. 13 shows a third embodiment of the recording method according to the invention, which is an alternative to the method shown in FIG. 12.

The method shown in FIG. 13 differs from the method shown in FIG. 12 in that the steps for deposition of a transparent material and for deposition of a new opaque layer are replaced by a step for bonding of an intermediate transparent substrate 131 (step 132) onto the previously etched opaque layer. A new opaque layer 45 may have been deposited on the intermediate transparent substrate 131 before bonding 132. Alternatively, a new opaque layer 45 is deposited onto the intermediate transparent substrate 131 after bonding 132.

Bonding is carried out, for example, using a resin 133. Alternatively it is carried out using molecular adhesion. The intermediate transparent substrate 131 is, for example, a film of glass with a thickness of 30 μm to 100 μm.

FIG. 14 shows a fourth embodiment of the recording method according to the invention.

According to this fourth embodiment the first transparent substrate 41 is covered by the first opaque layer 42. The first opaque layer 42 is etched using photo-lithography (step 140).

The method then comprises step 142 for deposition of a new opaque layer 45 directly onto the previously etched opaque layer. The new opaque layer 45 is then etched using photo-lithography (step 143).

The method then comprises a final step 144 of bonding the second transparent substrate 46 onto the previously etched opaque layer.

Steps 142 and 143 form a cycle which may be repeated as many times as desired. In other words, this fourth embodiment of the method according to the invention has at least one cycle comprising the following steps (with the previously etched opaque layer being initially the first opaque layer):
bonding of a new opaque layer onto the previously etched opaque layer;
etching, using photo-lithography, of the new opaque layer, with the new opaque layer then forming the previously etched opaque layer.

FIG. 15 shows a storage medium 150 according to the invention comprising a high-definition storage zone 151 (in black) and a low-definition storage zone 152 (in grey). In other words, the high-definition storage zone does not correspond to the total extent of the data stored in the storage medium 150.

In order to simplify the description, reference will be made to a high-definition storage zone 151 and a low-definition storage zone 152, but in reality there are several of these: a low- or high-definition storage zone corresponds to one source image and a given medium holds several reproductions of source images.

Also seen in FIG. 15 are the two portions 155, 156 of the storage medium before it is assembled (this case is that of a method according to the first embodiment as described with reference to FIGS. 11A and 11B).

Portion 155 represents the main part of the medium, with the thickest opaque layer. Here there are a documents storage zone 155₁, a reference zone 155₂ (title of the medium, table of contents etc.) and calibration zones and alignment cross-wires 155₃.

The reference zone 155₂ does not have high-definition information, and therefore it does not need to use the method according to the invention. The document storage zone 155₁ may also comprise low-definition data which can be processed by a single opaque layer method according to the prior art. These zones, which do not have any high-definition information, are not found in the second part 156 of the storage medium. The processing of the second part 156 of the storage medium can thus be speeded up.

In the case where a colour image must be stored, this is broken down (or decomposed) into three components, with each component being stored independently. It may be envisaged that some components are stored using a single opaque layer, as in the prior art, and that other components are stored using at least two superimposed opaque layers by a storage process according to the invention.

For example, an image is broken down on the basis of the HSV or LAB decomposition methods. The chromatic component or components determine the dynamic range of the image colour. Thus the choice will be made to store the chromatic component or components using a method according to the invention in the high-definition storage zone 151 of the storage medium. The other components are stored in the low-definition storage zone 152 of the storage medium.

For example an image to be stored is broken down using LAB decomposition to obtain a light intensity component, a first chromatic component and a second chromatic component. The first and second chromatic components are stored in the high-definition storage zone 151 and the light intensity component is stored in the low-definition storage zone 152.

An image to be stored could also be broken down in accordance with HSV decomposition in order to obtain a “hue” component, a “saturation” component and a “light intensity” component. The “hue” and “saturation” components are stored in the high-definition storage zone 151 and the “light intensity” component is stored in the low-definition storage zone 152.

One component could also be favoured by providing a reduced reproduction of this component of the image, using a lower reduction factor.

FIG. 16 shows a comparison of the mean square error between a source image and its representation in the form of elementary patterns, in the case of storage according to the prior art and in the case of storage according to the invention.

More accurately, a source image and an image obtained after optical detection of its representation in the form of elementary patterns are compared. The optical detection is that described with reference to FIG. 3 using an optical system which introduces optical blur similar to a Gaussian spot of width wg. This is optical detection using Gaussian convolution.

The abscissa axis corresponds to the width wg of the Gaussian relative to the size of the cell.

The ordinate axis corresponds to the mean square error in relation to the source image.

The source image is a grid of grey level tonalities made up of 20×20 zones of different greys randomly distributed in space and within the dynamic range 0 to 255. The zones have an extent of 3×3 pixels; that is, an image to be coded of 60×60 pixels.

Graph 161 corresponds to a storage method according to the prior art which uses a single platinum oxide layer of thickness 45 nm and amplitude modulation screening which uses circular openings in opaque cells. The step interval of the addressing matrix is 0.02 μm. A square cell with sides whose length Λ is equal to 2 μm is used (see FIG. 8). The minimum error is about 2%.

Graph 162 corresponds to a storage method according to the invention which uses two platinum oxide layers of thickness 45 nm and 30 nm and amplitude modulation screening which uses circular openings in opaque cells. Here again the address matrix step interval is 0.02 μm and a square cell, the length Λ of whose sides is equal to 2 μm, is used. The minimum error is about 0.6%, that is about 3 times less than the error obtained with the method according to the prior art under similar conditions.

This figure does not take the detection dynamic range, which is also improved by the method according to the invention, into consideration.

The invention is not limited to the embodiments that have been described. In particular, all forms of openings etched in an opaque layer, other opaque layer thicknesses, and other materials forming the transparent substrates or the opaque layers can also be envisaged.

For some of the figures relating to the invention, the case of superimposition of two opaque layers has been shown. These examples can of course be extended to the case where more than two opaque layers are superimposed.

1. A method of recording a source image, wherein a reproduction of the source image is made in the form of a matrix of elementary patterns, said reproduction being intended for transparency reading, and the method comprising the following steps:
deposition of a first opaque layer on a first substrate;
etching of the first opaque layer over an entire thickness by photo-lithography, so as to form a matrix of first cells each having one from amongst several predetermined patterns;
depositing at least one second opaque layer so that the second opaque layer is superimposed on the first opaque layer; and
etching said second opaque layer over an entire thickness by photo-lithography, so as to form on the second opaque layer a matrix of second cells each of which has one from amongst several second predetermined patterns, said elementary patterns each being defined by superimposition of a first pattern from amongst several said first predetermined patterns and a second pattern from amongst said second predetermined patterns, and where at least one elementary pattern is defined by a first pattern being superimposed on a second pattern which is different from said first pattern.

2. A recording method according to claim 1, further comprising carrying out storage of a source image in a storage medium comprising a first transparent substrate and a second transparent substrate,
forming the first opaque layer is formed on the first transparent substrate;
carrying out the etching steps using maskless photo-lithography; and
depositing a second opaque layer so that the second opaque layer is between the first opaque layer and the second transparent substrate.

3. The method according to claim 1, wherein the first and second opaque layers exhibit respective degrees of opacity which differ from one another.

4. The method according to claim 1, wherein the first and second opaque layers have different thicknesses and are formed of the same material.

5. The method according to claim 1, wherein:
each first cell and each second cell is either fully etched or non-etched, thus defining, by superimposition, a first series of elementary patterns available to carry out reproduction of the source image; and
frequency modulation screening of the source image is performed using coding patterns chosen from amongst said first series of elementary patterns.

6. The method according to claim 1, wherein:
each first cell and each second cell is etched, or non-etched, or etched so as to form a closed transparent area in a cell with opaque edges or a closed opaque area in a cell with transparent edges, thus defining, by superimposition, a second series of elementary patterns available for carrying out the reproduction of the source image; and
amplitude modulation screening of the source image is performed using coding patterns chosen from amongst said second series of elementary patterns.

7. The method according to claim 2, comprising the following steps:
decomposition of an image to be stored into three components;
recording of said three components, each in a storage zone of the storage medium and between the first transparent substrate and the second transparent substrate, at least one of said components being recorded in a storage zone, called the high-definition storage zone, using a method according to any of claim 2, and where at least one of said components is recorded in a storage zone, called the low-definition storage zone, by etching a single opaque layer using photo-lithography.

8. The method according to claim 7, wherein an image to be stored is broken down using a HSV decomposition to obtain a “hue” component, a “saturation” and a “light intensity” component, the “hue” and “saturation” components are recorded in the high-definition storage zone, and the “light intensity” component is recorded in the low-definition storage zone.

9. The method according to claim 1, wherein a step for reading a reproduction of a source image, with transparency reading, comprising the following steps:
illuminating said reproduction using a light source located on one side of said reproduction;
detecting an image of said reproduction, using a detector located on the side of said reproduction away from that of the light source.

10. An image medium obtained by using a method according to claim 1, wherein a reproduction of a source image is stored in the form of a juxtaposition of elementary patterns, said reproduction being intended to be read in transparency and said image medium comprising, on a first substrate, a first opaque layer etched over its entire thickness using photo-lithography and forming a matrix of first cells each having one from amongst several predetermined first patterns;
wherein:
the image medium comprises at least one second opaque layer, etched over its entire thickness using photo-lithography, forming a matrix of second cells, each second cell having one from amongst several second predetermined patterns; and
the second opaque layer is located on the first opaque layer so as to define said elementary patterns, formed by the superimposition of a first pattern and a second pattern, and at least one elementary pattern being defined by the superimposition of a first pattern on a second pattern which is different from said first pattern.

11. The image medium according to claim 10, wherein said image medium forms a storage medium for the source image and:
wherein said image medium comprises at least one storage zone, called the high-definition zone, wherein the reproduction of the source image is stored;
wherein said image medium comprises a first transparent substrate and a second transparent substrate, the first opaque layer being located on the first transparent substrate and the second opaque layer being located between the first opaque layer and the second transparent substrate.

12. The image medium according to claim 10, wherein the first opaque layer and the second opaque layer have different thicknesses, each thickness being between 10 nm and 200 nm.

13. The image medium according to claim 10, wherein each first cell and second cell is either fully etched or not etched.

14. The image medium according to claim 10, wherein each first cell and second cell is fully etched or not etched, or etched so as to form a closed transparent area in a cell with opaque edges or a closed opaque area in a cell with transparent edges, closed areas formed in various first cells having different dimensions, closed areas formed in different second cells having different dimensions.

15. The image medium according to claim 11, comprising:
a first high-definition storage zone, wherein a reproduction of a first source image is stored which corresponds to a first from amongst three components of an image to be stored;
a first low-definition storage zone, wherein a reproduction of a second source image is stored which corresponds to the second component of the image to be stored, the low-definition storage zone comprising, between the first transparent substrate, a single opaque layer etched using photo-lithography; and
a second high-definition storage zone or a second low-definition storage zone wherein a reproduction of a third source image is stored which corresponds to the third component of the image to be stored.
